(19) United States
(12) Patent Application Publication
(10) Pub. No.: US 2019/0304777 A1
(43) Pub. Date: Oct. 3, 2019

(54) METHOD FOR FORMING HARD MASK

(71) Applicants: UNITED MICROELECTRONICS CORP., Hsin-Chu City (TW); Fujian Jinhua Integrated Circuit Co., Ltd., Quanzhou City (CN)

(72) Inventors: Feng-Yi Chang, Tainan City (TW); Fu-Che Lee, Taichung City (TW); Ying-Chih Lin, Tainan City (TW); Gang-Yi Lin, Taitung County (TW)

(21) Appl. No.: 15/964,031

(22) Filed: Apr. 26, 2018

(30) Foreign Application Priority Data
Mar. 29, 2018 (CN) 201810272485.8

(51) Int. Cl. H01L 21/02; H01L 21/033

(52) U.S. Cl. CPC H01L 21/02337; H01L 21/0338; H01L 21/0337

(57) ABSTRACT

The present invention provides a method for fabricating a hard mask, comprising: firstly, a first material layer and a second material layer are provided on the first material layer, a cell region and a peripheral region are defined thereon, and then a plurality of sacrificial patterns and a plurality of spacers are formed in the cell region on the second material layer, each two spacers are located at two sides of each of the sacrificial patterns. Afterwards, a first etching step is performed to remove the sacrificial patterns, a second etching step is performed to remove a portion of the second material layer and expose a portion of the first material layer within the cell region, and a third etching step is performed to remove portions of the first material layer, so as to forma plurality of first recesses in the first material layer.

### BACKGROUND OF THE INVENTION

### 1. Field of the Invention

The present invention relates to the field of semiconductor processing, and more particularly to a method of fabricating a hard mask.

### 2. Description of the Prior Art

With the trend in the industry being towards scaling down the size of the metal oxide semiconductor transistors (MOS), three-dimensional or non-planar transistor technology, such as fin field effect transistor technology (Fin FET), has been developed to replace planar MOS transistors. In current techniques, in order to achieve sub-lithographic features, a regular photolithography and an etching process accompanied with a pullback process are performed to form fin structures in Fin FETs.

However, as the size of the FETs shrink, the electrical and physical requirements in each part of the multi-gate FET become critical, like the sizes and shapes of the fin-shaped structures and the spacing between each fin-shaped structure for example. Thus, how to reach standard requirements and overcome the physical limitations has become an important issue in the industry of the FETs.

In the conventional art, if there are different regions (such as the isolation region and dense regions) defined on the substrate, the density of the elements in each region is not uniform. As a result, each region has different top surface heights after filling in the dielectric layer, which will affect the subsequent process yield. In particular, the uneven top surface is not useful for the production of a multilayer structure.

### SUMMARY OF THE INVENTION

The present invention provides a method for fabricating a hard mask, comprising: firstly, a first material layer and a second material layer are provided on the first material layer, a cell region and a peripheral region are defined thereon, and then a plurality of sacrificial patterns and a plurality of spacers are formed in the cell region on the second material layer, each two spacers are located at two sides of each of the sacrificial patterns. Afterwards, a first etching step is performed to remove the sacrificial patterns, a second etching step is performed to remove a portion of the second material layer and expose a portion of the first material layer within the cell region, and a third etching step is performed to remove portions of the first material layer, so as to forma plurality of first recesses in the first material layer.

The present invention is characterized in that, since the cell region contains more components in a limited area, it is easy to cause the top surface of the dielectric layer in the cell region to protrude when the dielectric layer is subsequently formed. In order to avoid the above situation, in the process of fabricating a hard mask, a plurality of first recesses are first formed in the cell region, and the first recesses can reduce the top surface of the dielectric layer in the cell region, in this way, the formed dielectric layer will have a relatively flat top surface. As a result, other material layers stacked on the dielectric layer can also be formed on a flat surface, thereby improving the yield of the entire semiconductor device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a process of fabricating a hard mask according to the first preferred embodiment of the present invention.

FIG. 8 shows a top view of the hard mask and the second hard mask.

FIG. 9 is a top view of a hard mask and a second hard mask according to another embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

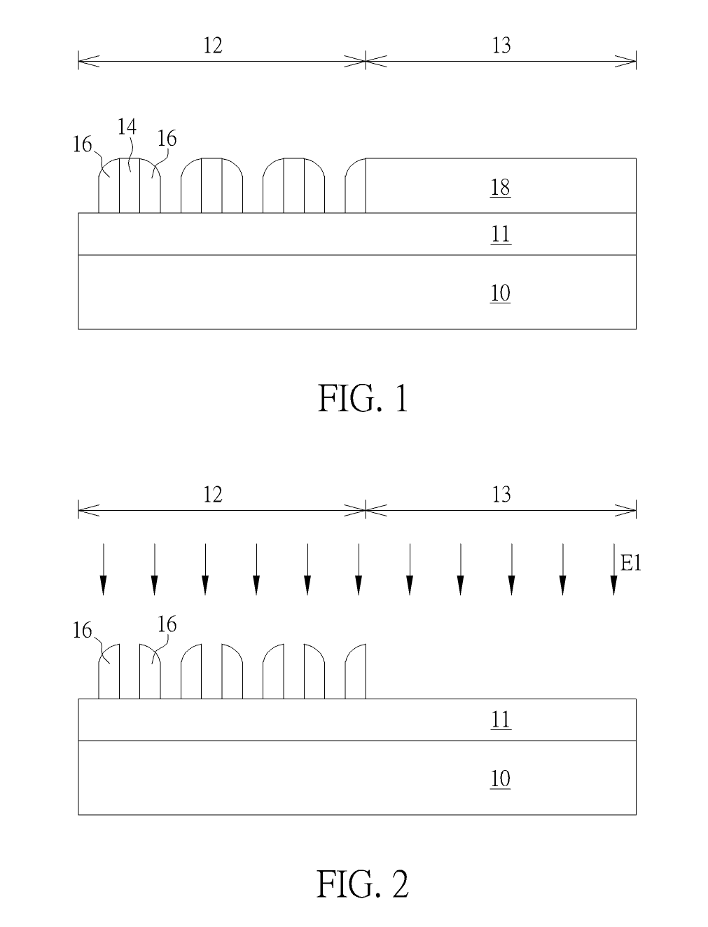

FIGS. 1-7 illustrate a process of fabricating a hard mask according to a first preferred embodiment of the present invention. As shown in FIG. 1, a first material layer 10 and a second material layer 11 are provided to cover the first material layer 10. A cell region 12 and a peripheral region 13 are also defined. The material of the first material layer 10 is, for example, silicon nitride (SiN), and the material of the second material layer 11 is, for example, silicon oxynitride (SiON). In a subsequent step, the first material layer 10 and the second material layer 11 are made into a hard mask, and then the pattern of the hard mask is transferred to a target layer (not shown) disposed below. The target layer is, for example, a substrate or other material layer. The cell region 12 and the peripheral region 13 correspond to the cell region and the peripheral region of the subsequently completed semiconductor device. In general, the element density in the cell region is higher than the element density in the peripheral region.

Please still refer to FIG. 1, in the cell region 12, a plurality of sacrificial layer patterns 14 are formed on the second material layer 11. In one embodiment, the sacrificial layer pattern 14 is a polysilicon gate or an organic dielectric layer (ODL), but its material is not limited thereto, depending on actual requirements. A plurality of spacers 16 are then formed beside each sacrificial layer pattern 14. Furthermore, a sacrificial material (not shown) is conformally coated on each of the sacrificial layer patterns 14 and the second material layer 11, and then the sacrificial material is etched to form the spacers 16. This step can be integrated with the conventional gate process. The spacer 16 may be, for example, a silicon nitride spacer, but the invention is not limited thereto. The spacers 16 may have an etching selectivity with the sacrificial layer pattern 14. Furthermore, each of the spacer 16 is not limited to a single layer structure, and it may have a multilayer structure.

In addition, in the peripheral region 13, a first dielectric layer 18 is preferably formed. The first dielectric layer 18 is, for example, an organic dielectric layer (ODL), but is not limited thereto. In addition, the top surface of the first dielectric layer 18 is preferably aligned with the top surface of the sacrificial layer pattern 14.

Next, as shown in FIG. 2, a first etching step E1 is performed to completely remove the sacrificial layer patterns 14 and the first dielectric layer 18, so only the spacers 16 are remained on the second material layer 11, and a portion of the second material layer 11 located right under each sacrificial layer pattern 14 is then exposed.

As shown in FIG. 3, a second etching step E2 is performed to remove a portion of the second material layer 11 in the cell region 12 and the peripheral region 13. In more detail, in the present embodiment, the second etching step uses the etching gas with fluoromethane (CH₃F) to remove the second material layer 11 in the cell region 12 and the peripheral region 13. It is worth noting that the applicant founded that during the etching process for etching the SiON, some polymer particles 20 are gradually deposited on the surface of the second material layer 11 in the chamber. The polymer particles 20 will also be exhausted out of the chamber during the second etching step E2. However, the applicant has found that since there are more components disposed in the cell region 12, for example, a recess formed between the spacers 16. With the effect of enhancing the air flow, and the efficiency of pumping away the polymer particles 20 in the cell region 12 is better, so less polymer particles 20 remain in the cell region 12. On the other hand, the efficiency of pumping away the polymer particles 20 in the peripheral region 13 is poor, so that a part of the polymer particles 20 is deposited on the second material layer 11 and the etching rate of the second material layer 11 in the peripheral region 13 is slowed down. Therefore, after the second etching step E2 is completed, in the cell region 12, the pattern can be completely transferred into the second material layer 11 by using the remaining spacers 16 as hard masks, until the top surface of some of the first material layer 10 is exposed. However, since the etching rate is relatively slow in the peripheral region 13, there is still a portion of the second material layer 11 remaining on the first material layer 10. In other words, the first material layer 10 in the peripheral region 13 is still completely covered by the second material layer 11.

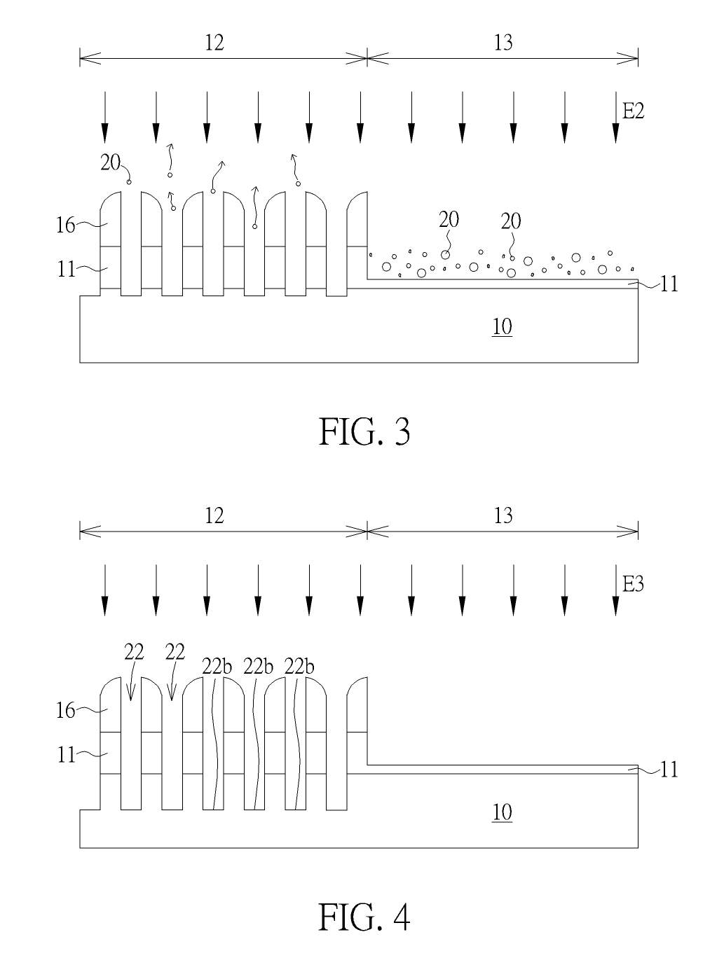

As shown in FIG. 4, a third etching step E3 is performed to remove part of the first material layer 10 in the cell region 12, and to form a plurality of first recesses 22. In addition, the third etching step E3 also removes the above-described polymer particles 20 deposited on the surface of the second material layer 11 simultaneously. In more detail, in the present embodiment, the third etching step E3 includes etching gas includes such as oxygen (O₂), carbon monoxide (CO), carbon dioxide (CO₂), sulfur dioxide (SO₂), and carbon sulfur oxide (COS). The third etching step E3 (etching gas) can effectively etch the first material layer 10 (for example, silicon nitride), but it is difficult to etch the second material layer 11 (for example, silicon oxynitride). Therefore, in the cell region 12, the exposed first material layers 10 will be effectively etched, but within the peripheral region 13, since all the first material layers 10 are still covered by the second material layers 11, so the first material layer 10 will not be etched. In addition, in the present embodiment, each bottom surface of each first recess 22 is defined as 22b, and each bottom surface 22b of each first recess 22 are substantially aligned with each other.

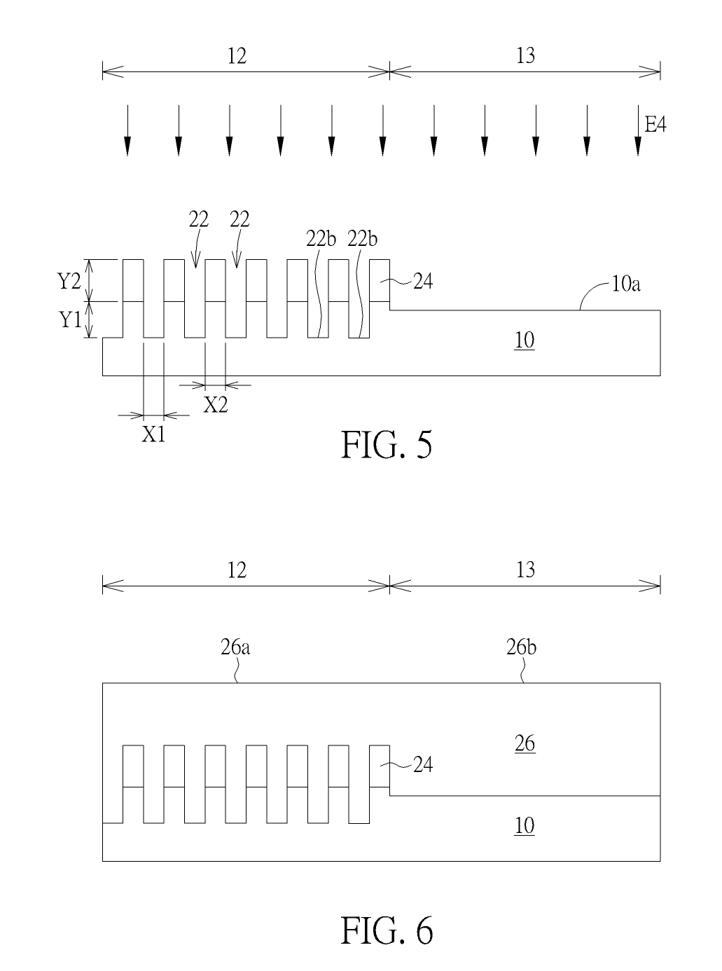

Then, as shown in FIG. 5, a fourth etching step E4 is performed to remove the second material layer 11 in the peripheral region 13, and to remove the remaining spacers 16 in the cell region 12. The fourth etching step E4 mentioned above may include multiple etching steps to remove the second material layer 11 in the peripheral region 13 and to remove the remaining spacers 16 in the cell region 12 respectively. In addition, after the second material layer 11 in the peripheral region 13 is removed, a top surface of the first material layer 10 in the peripheral region 13 is defined as 10a, and the top surface 10a is higher than the bottom surface 22b of each first recess 22.

It is worth noting that after the fourth etching step E4 is performed, each remaining second material layer 11 in the cell region 12 is defined as a hard mask 24. In other words, at this time, the cell region 12 includes a plurality of first recesses 22 and a plurality of hard masks 24. From the sectional view, the width of each first recess 22 is labeled as X1 and the depth of each first recess 22 is labeled as Y1, and the width of each hard mask 24 is labeled as X2 and the height of each hard mask 24 is labeled as Y2. The depth Y1 of the first recess 22 can be changed by adjusting the parameter of the third etching step E3. For example, the longer the etching time of the third etching step E3, the larger the depth Y1. In this embodiment, the ratio of X1Y1/X2Y2 is preferably between 0.9-1.1, but is not limited thereto. That is, the cross-sectional area of each first recess 22 is approximately equal to the cross-sectional area of each hard mask 24. As a result, when a dielectric layer (not shown) is subsequently formed to cover the cell region 12, the declining of the top surface of the dielectric layer caused by the first recess 22 will compensate for the rising of the top surface of the dielectric layer caused by the hard mask 24. Therefore, the dielectric layer has a relatively flat top surface.

In more detail, as shown in FIG. 6, a second dielectric layer 26 is formed to cover the cell region 12 and the peripheral region 13. The material of the second dielectric layer 26 is, for example, an organic dielectric layer (ODL), but is not limited thereto. In this step, since a plurality of first recesses 22 are already formed in the cell region 12, part of the second dielectric layer 26 will fill in the first recess 22, to avoid the rising of the top surface of the second dielectric layer 26 caused by the hard masks 24 in the cell region 12. Therefore, the top surface of the second dielectric layer 26 in the cell region 12 will not higher than the top surface of the second dielectric layer 26 in the peripheral region 13. In this embodiment, in the process without performing any planarization step, the top surface of the second dielectric layer 26 in the cell region 12 is defined as top surface 26a, and the top surface of the second dielectric layer 26 in the peripheral region 13 is defined as top surface 26b, and the top surface 26a is aligned with the top surface 26b.

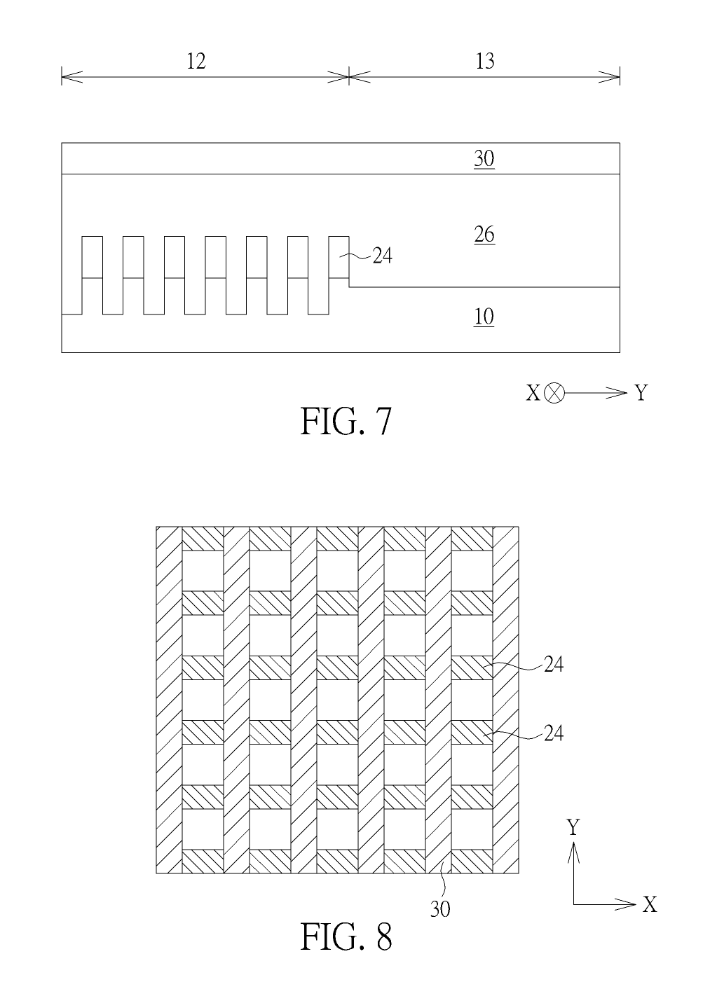

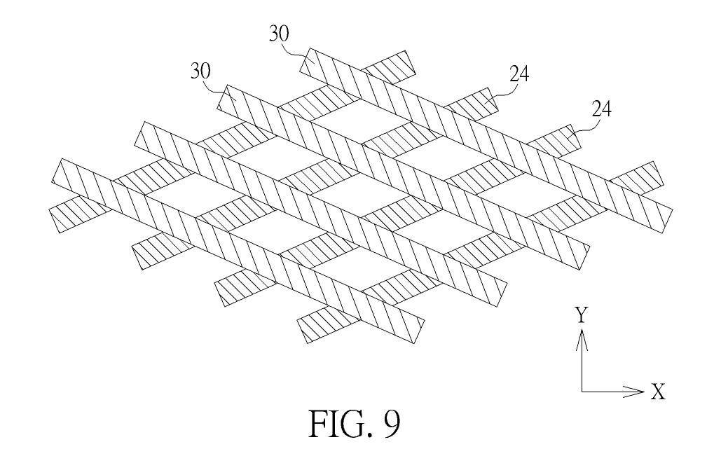

In a following steps, as shown in FIG. 7, a second hard mask 30 may be further formed on the second dielectric layer 26 using steps similar to those shown in FIGS. 1-6, the material of the second hard mask 30 is, for example, silicon oxynitride (SiON), but not limited thereto. In addition, if the hard mask 24 comprises a plurality of stripe structures arranged in a first direction (for example, the X-axis direction), the second hard mask 30 may comprise a plurality of stripe structures arranged along a second direction (for example, the Y-axis direction). For example, please refer to FIG. 8, which illustrates a top view of the hard mask 24 and the second hard mask 30 according to one embodiment of the present invention. Furthermore, the first direction and the second direction are not limited to the X-axis direction and the Y-axis direction, and may be two directions are not parallel to each other. For example, please refer to FIG. 9, which illustrates a top view of the hard mask 24 and the second hard mask 30 according to another embodiment of the present invention. In FIG. 9, both the hard mask 24 and the second hard mask 30 are not perpendicular to each other. The manufacturing process of the second hard mask 30 is substantially the same as that of the conventional hard mask, which is not described here. In the subsequent steps, the patterns of the hard mask 24 and the second hard mask 30 can be simultaneously transferred to a target layer (not shown) disposed below, to form a structure such as a contact hole or a storage node pad. The methods are well known in the art and are not described here in detail.

The present invention is characterized in that, since the cell region contains more components in a limited area, it is easy to cause the top surface of the dielectric layer in the cell region to protrude when the dielectric layer is subsequently formed. In order to avoid the above situation, in the process of fabricating a hard mask, a plurality of first recesses are first formed in the cell region, and the first recesses can reduce the top surface of the dielectric layer in the cell region, in this way, the formed dielectric layer will have a relatively flat top surface. As a result, other material layers stacked on the dielectric layer can also be formed on a flat surface, thereby improving the yield of the entire semiconductor device.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating a hard mask, comprising:
providing a first material layer and a second material layer disposed on the first material layer, a cell region and a peripheral region are defined thereon, wherein the material of the first material layer comprises silicon nitride, and the material of the second material layer comprises SiON;
forming a plurality of sacrificial patterns and a plurality of spacers in the cell region on the second material layer, each two spacers are located at two sides of each of the sacrificial patterns, wherein the material of the sacrificial patterns does not comprises SiON;
performing a first etching step, to remove the plurality of sacrificial patterns, wherein the first etching step is a reactive ion etching;
performing a second etching step, to remove a portion of the second material layer and to expose a portion of the first material layer within the cell region, wherein the second etching step is a reactive ion etching; and
performing a third etching step, to remove portions of the first material layer, so as to form a plurality of first recesses in the first material layer.

2. The method of claim 1, wherein the first material layer in the peripheral region is not etched when the third etching step is performed.

3. The method of claim 1, wherein the first material layer in the peripheral region is still completely covered by the second material layer during the second etching step is performed.

4-5. (canceled)

6. The method of claim 1, wherein the second etching step comprises fluoromethane (CH₃F).

7. The method of claim 1, wherein the third etching step includes oxygen (O₂), carbon monoxide (CO), carbon dioxide (CO₂), sulfur dioxide (SO₂), and carbon sulfur oxide (COS).

8. The method of claim 1, wherein some polymer particles are deposited on the second material layer of the peripheral region when the second etching step is performed.

9. The method of claim 1, wherein a first dielectric layer is formed in the peripheral region while the sacrificial layer is formed, wherein a material of the first dielectric layer is different from a material of the second material layer.

10. The method of claim 9, wherein a top surface of the first dielectric layer is aligned with a top surface of the sacrificial layer pattern.

11. The method of claim 9, wherein the first dielectric layer is completely removed in the first etching step.

12. The method of claim 1, further comprising performing a fourth etching step to completely remove the second material layer in the peripheral region after the third etching step is performed.

13. The method of claim 12, wherein a bottom surface of each of the plurality of first recesses formed in the cell region is substantially aligned with each other.

14. The method of claim 13, wherein a top surface of the first material layer in the peripheral region is higher than a bottom surface of each of the first recesses in the cell region.

15. The method of claim 12, further comprising forming a second dielectric layer, to cover the cell region and the peripheral region after the fourth etching step is performed.

16. The method of claim 15, wherein the second dielectric layer in the cell region has a first top surface, the second dielectric layer in the peripheral region has a second top surface, and the first top surface is aligned with the second top surface.
